(19) United States
(12) Patent Application Publication
(10) Pub. No.: US 2013/0316519 A1
(43) Pub. Date: Nov. 28, 2013

(54) Techniques for Forming a Chalcogenide Thin Film Using Additive to a Liquid-Based Chalcogenide Precursor

(71) Applicants: David Brian Mitzi, Mahopac, NY (US); Xiaofeng Qiu, Sleepy Hollow, NY (US)

(72) Inventors: David Brian Mitzi, Mahopac, NY (US); Xiaofeng Qiu, Sleepy Hollow, NY (US)

(73) Assignee: International Business Machines Corporation, Armonk, NY (US)

(21) Appl. No.: 13/479,856

(22) Filed: May 24, 2012

(51) Int. Cl. H01L 21/36

(52) U.S. Cl. 438/478; 257/E21.461

(57) ABSTRACT

Techniques for enhancing energy conversion efficiency in chalcogenide-based photovoltaic devices by improved grain structure and film morphology through addition of urea into a liquid-based precursor are provided. In one aspect, a method of forming a chalcogenide film includes the following steps. Metal chalcogenides are contacted in a liquid medium to form a solution or a dispersion, wherein the metal chalcogenides include a Cu chalcogenide, an M1 and an M2 chalcogenide, and wherein M1 and M2 each include an element selected from the group consisting of: Ag, Mn, Mg, Fe, Co, Cd, Ni, Cr, Zn, Sn, In, Ga, Al, and Ge. At least one organic additive is contacted with the metal chalcogenides in the liquid medium. The solution or the dispersion is deposited onto a substrate to form a layer. The layer is annealed at a temperature, pressure and for a duration sufficient to form the chalcogenide film.

### FIELD OF THE INVENTION

The present invention relates to photovoltaic devices, such as solar cells, and more particularly, to techniques for enhancing energy conversion efficiency in chalcogenide-based photovoltaic devices by improved grain structure and film morphology (e.g., crack and pinhole free) through addition of urea into a liquid-based precursor.

### BACKGROUND OF THE INVENTION

Copper quaternary chalcogenide compounds and alloys are among the most promising absorber materials for photovoltaic applications, due to their tunable and direct band gap, and very high optical absorption coefficient in the visible and near-infrared (IR) spectral range. Traditionally, these high performance thin film photovoltaic compounds (such as copper indium gallium selenide (CIGS)) are produced by vacuum-based thin film deposition techniques, which require sophisticated equipment, high processing temperatures (typically above 450 degrees Celsius (° C.)), and usually a post-deposition treatment in a chalcogen (S or Se)-rich atmosphere (such as Se vapor or hydrogen selenide/sulfide (H₂Se/H₂S)). Solution-based thin film deposition techniques are regarded as a possible route to overcome the cost and scalability issues faced by photovoltaic technology in terms of competing with entrenched carbon-based electricity production methods. In recent years, solution-processed copper zinc tin sulfide (CZTS) or its selenide analogues have emerged as very promising alternative photovoltaic absorber materials because of not only using earth abundant and nontoxic elements, but also the factor that the solution-processed CZTS devices are more efficient than the vacuum-deposited devices. See, for example, T. Todorov, K. Reuter, D. B. Mitzi, “High-Efficiency Solar Cell With Earth-Abundant Liquid-Processed Absorber,” Adv. Mater. 22, E156-E159 (2010); S. Bag, O. Gunawan, T. Gokmen, Y. Zhu, T. K. Todorov, D. B. Mitzi, “Low band gap liquid-processed CZTSe solar cell with 10.1% efficiency,” Energy Environ. Sci., Issue 5, February 2012, DOI: 10.1039/c2ee00056c; and B. Shin, O. Gunawan, Y. Zhu, N. A. Bojarczuk, S. J. Chey, S. Guha, “Thin film solar cell with 8.4% power conversion efficiency using an earth-abundant Cu₂ZnSnS₄ absorber,” Prog. Photovolt: Res. Appl. (2011) DOI: 10.1002/pip.

This family of absorbers, also referred to as kesterites, consists of Cu₂ZnSnS₄ (CZTS), as well as Cu₂ZnSnSe₄ (CZTSe) and more generally Cu₂ZnSn(S, Se)₄ (CZTSSe), with the S:Se ratio governing the band gap in the material. Besides tailoring the band gap using the S:Se ratio, substitution of Ge for Sn (i.e., Cu₂Zn(Sn,Ge)(S,Se)₄) can also be employed. The above family of materials will be generally referred to as CZTS-based.

A challenge faced by solution-based deposition methods is the difficulty in controlling the grain structure and film morphology of the absorber layer. Small grain size and poor film morphology severely limit solar cell efficiency. Namely, grain boundaries can act as recombination centers for the photogenerated electrons and holes, which is detrimental to the device performance. In general, grain sizes on the order of absorber layer thickness (micrometer (μm)-length scale) are desirable in order to minimize such recombination effects. Film cracks and/or pinholes are another problem limiting the quality of the absorber layer, as cracks and pinholes can lead to device shunting. Therefore, approaches that result in good grain structure and crack- and pinhole-free films would be desirable.

So far the best CZTS-based photovoltaic devices are prepared by a hydrazine-based solution technique. See, for example, T. Todorov et al., “High-Efficiency Solar Cell with Earth-Abundant Liquid-Processed Absorber,” Adv. Mater. 22, E156-E159 (2010). With this approach, over 10% energy conversion efficiency has been achieved. See, for example, S. Bag, O. Gunawan, T. Gokmen, Y. Zhu, T. K. Todorov, D. B. Mitzi, “Low band gap liquid-processed CZTSe solar cell with 10.1% efficiency,” Energy Environ. Sci., Issue 5, February 2012, DOI: 10.1039/c2ee00056c; D. A. R. Barkhouse, O. Gunawan, T. Gokmen, T. K. Todorov, D. B. Mitzi, “Device characteristics of a 10.1% hydrazine-processed Cu₂ZnSn(Se,S)₄ solar cell,” Prog. Photovolt: Res. Appl. 20, 6-11 (January 2012). However, hydrazine is an explosive and highly toxic solvent, which must be used under carefully controlled conditions (generally in an inert atmosphere such as nitrogen or argon). Therefore, there is a need to develop approaches that do not employ hydrazine, but still enable the deposition of high-quality films.

An alternative hydrazine-free nanoparticle-based method yielded a CZTS photovoltaic device with 7.2% efficiency using organic amines. See Q. Guo, G. M. Ford, W. Yang, B. C. Walker, E. A. Stach, H. W. Hillhouse, R. Agrawal, “Fabrication of 7.2% Efficient CZTSSe Solar Cells Using CZTS Nanocrystals,” J. Am. Chem. Soc., 2010, 132, 17384-17386. Although this method avoided using highly toxic and explosive hydrazine, it involves heavy use of toxic and expensive organic reagents and an anneal in toxic selenium vapor, which therefore does not necessarily eliminate the safety and environmental problems, but may also introduce unwanted carbon impurities and negatively impact the device performance. The same group also reported the preparation of a CZTS photovoltaic device using less expensive and less toxic dimethyl sulfoxide (DMSO) as solvent. This method yielded an energy conversion efficiency of 4.1%, which may be limited by the small grains (on the order of a couple of hundred nanometers or smaller). See W. Ki, H. W. Hillhouse, “Earth-Abundant Element Photovoltaics Directly from Soluble Precursors with High Yield Using a Non-Toxic Solvent,” Adv. Energy Mater., 2011, 1, 732-735.

Patent Application Number WO2011/066205A1, filed by L. K. Johnson et al. entitled “Aqueous process for producing crystalline copper chalcogenide nanoparticles, the nanoparticles so-produced, and inks and coated substrates incorporating the nanoparticles” introduced the synthesis of ink in an aqueous medium and developed kesterite CZTS thin films. Although, this method provided the possible route to make crystalline CZTS nanoparticles and films developed from such nanoparticles, it was not demonstrated to be useful in the preparation of high performance CZTS devices. On the other hand, the ligands and organic additives described therein may lead to unwanted carbon contamination in the films, which could impact the grain structures and film morphology, therefore possibly affecting the photovoltaic efficiency.

U.S. Patent Application Publication Number 2011/0097496 A1 filed by Mitzi et al., entitled “Aqueous-Based Method of Forming Semiconductor Film and Photovoltaic Device Including the Film” provides an aqueous-based non-hydrazine approach to prepare CZTS thin films and photovoltaic devices. However, it has been found that the CZTS films prepared by this method without any hydrazine exhibit small grains (a couple of hundred nanometers) and surface cracking. The best devices fabricated from these films reached efficiency of around 7%.

The above-described approaches generally either employ hydrazine or, for water-based approaches, generally have issues with reproducibly being able to produce CZTS films with good morphology and grain size, particularly for pure sulfide CZTS films. Therefore, a method of improving the grain structure and film morphology of CZTS/CZTSe-based absorber layer prepared from non-toxic solution-based techniques, preferrably an aqueous solution, would be desirable.

### SUMMARY OF THE INVENTION

The present invention provides techniques for enhancing energy conversion efficiency in chalcogenide-based photovoltaic devices by improving grain structure and film morphology through addition of urea into a liquid-based precursor. In one aspect of the invention, a method of forming a chalcogenide film is provided. The method includes the following steps. Metal chalcogenides are contacted in a liquid medium to form a solution or a dispersion, wherein the metal chalcogenides include a Cu chalcogenide, an M1 chalcogenide and an M2 chalcogenide, and wherein M1 and M2 each include an element selected from the group including: Ag, Mn, Mg, Fe, Co, Cd, Ni, Cr, Zn, Sn, In, Ga, Al, and Ge. Optionally, an additional M3 chalcogenide or M3 salt is contacted with the metal chalcogenide, wherein M3 includes an element selected from the group including: Na, K, Li, Sb, Bi, Ca, Sr, Ba, and B. At least one organic additive is contacted with the metal chalcogenides in the liquid medium. The solution or the dispersion is deposited onto a substrate to form a layer. The layer is annealed at a temperature, pressure and for a duration sufficient to form the chalcogenide film.

In another aspect of the invention, a composition is provided. The composition includes at least one organic additive and metal chalcogenides in a liquid medium, wherein the metal chalcogenides include a Cu chalcogenide, an M1 chalcogenide and an M2 chalcogenide, and wherein M1 and M2 each include an element selected from the group including: Ag, Mn, Mg, Fe, Co, Cd, Ni, Cr, Zn, Sn, In, Ga, Al, and Ge. Optionally, the composition includes an additional M3 chalcogenide or M3 salt, wherein M3 includes an element selected from the group including: Na, K, Li, Sb, Bi, Ca, Sr, Ba, and B.

In another aspect of the invention, a photovoltaic device is provided. The photovoltaic device includes a substrate; a chalcogenide film formed on the substrate by the above-described method, which serves as an absorber layer; an n-type semiconducting layer on the chalcogenide film; and a top electrode on the n-type semiconducting layer. The photovoltaic device has a power conversion efficiency of greater than or equal to about 8.1%.

A more complete understanding of the present invention, as well as further features and advantages of the present invention, will be obtained by reference to the following detailed description and drawings.

### BRIEF DESCRIPTION OF THE DRAWINGS

FIG. 1 is a diagram illustrating an exemplary methodology for fabricating a metal chalcogenide film from additive-containing pure solution or particle-based routes according to an embodiment of the present invention;

FIG. 2 is a cross-sectional diagram illustrating a starting structure for fabricating a photovoltaic device, e.g., a substrate formed from a conductive material or a substrate coated with a layer of conductive material according to an embodiment of the present invention;

FIG. 3 is a cross-sectional diagram illustrating a chalcogenide film absorber layer having been formed on the substrate according to an embodiment of the present invention;

FIG. 4 is a cross-sectional diagram illustrating an n-type semiconducting layer having been formed on the chalcogenide film and a top electrode having been formed on the n-type semiconducting layer according to an embodiment of the present invention;

FIG. 5A is a scanning electron micrograph (SEM) image of a top view of a sample metal chalcogenide film prepared from ink containing no urea but some ammonium sulfide according to an embodiment of the present invention;

FIG. 5B is an SEM image of a top view of a sample metal chalcogenide film prepared from ink containing 0.2M urea and 0.5 atomic percent (at. %) NaF according to an embodiment of the present invention;

FIG. 5C is an SEM image of a cross-sectional view of the film of FIG. 5A according to an embodiment of the present invention;

FIG. 5D is a SEM image of a cross-sectional view of the film of FIG. 5B according to an embodiment of the present invention;

FIG. 6A is a SEM image of a top view of a sample metal chalcogenide film prepared from ink using only Na as additive according to an embodiment of the present invention;

FIG. 6B is a SEM image of a cross-sectional view of the film of FIG. 6A according to an embodiment of the present invention;

FIG. 6C is a SEM image of a top view of a sample metal chalcogenide film prepared from ink using only urea as additive according to an embodiment of the present invention;

FIG. 6D is a SEM image of a cross-sectional view of the film of FIG. 6C according to an embodiment of the present invention;

FIG. 6E is a SEM image of a sample metal chalcogenide film prepared from ink using both urea and Na as additives according to an embodiment of the present invention;

FIG. 6F is a SEM image of a cross-sectional view of the film of FIG. 6E according to an embodiment of the present invention;

FIG. 7A is a graph illustrating electrical characteristics of a photovoltaic device based on a metal chalcogenide film prepared using only Na as an additive according to an embodiment of the present invention;

FIG. 7B is a graph illustrating electrical characteristics of a photovoltaic device based on a metal chalcogenide film prepared using only urea as an additive according to an embodiment of the present invention;

FIG. 7C is a graph illustrating electrical characteristics of a photovoltaic device based on a metal chalcogenide film prepared using both Na and urea as additives according to an embodiment of the present invention;

FIG. 8A is a SEM image of a cross-sectional view of a sample metal chalcogenide film prepared using the present techniques according to an embodiment of the present invention;

FIG. 8B is a SEM image of a top view of the film of FIG. 8A according to an embodiment of the present invention;

FIG. 9 is a graph illustrating electrical characteristics of a photovoltaic device based on the film of FIGS. 8A and 8B according to an embodiment of the present invention;

FIG. 10A is a SEM image of a top view of another sample metal chalcogenide film prepared using the present techniques according to an embodiment of the present invention;

FIG. 10B is a SEM image of a cross-sectional view of the film of FIG. 10A according to an embodiment of the present invention;

FIG. 11 is a graph illustrating powder X-ray diffraction patterns of the film of FIGS. 10A and 10B according to an embodiment of the present invention;

FIG. 12 is a graph illustrating electrical characteristics of a photovoltaic device based on the film of FIGS. 10A and 10B according to an embodiment of the present invention;

FIG. 13A is a SEM image of a top view of yet another sample metal chalcogenide film prepared using the present techniques according to an embodiment of the present invention;

FIG. 13B is a SEM image of a cross-sectional view of the film of FIG. 13A according to an embodiment of the present invention; and

FIG. 14 is a graph illustrating electrical characteristics of a photovoltaic device based on the film of FIGS. 13A and 13B according to an embodiment of the present invention.

### DETAILED DESCRIPTION OF PREFERRED EMBODIMENTS

For clarity of description, definitions of some terms used throughout the description are now provided:

The term “ink,” as used herein refers to a liquid composed of at least one solvent, at least one kind of metal chalcogenide solid particle and at least one organic additive. The solvent can be water or nonaqueous solvent and accounts for from about 1% to about 99% of a weight of the ink. The solid metal chalcogenide particles account for from about 0.01% to about 50% of the weight of the ink. The shape of the solid metal chalcogenide particles can be, but is not limited to, spheres, cubes, rods, flakes and stars. The size of the solid metal chalcogenide particles (measured, for example, as a longest lateral dimension, e.g., longest width, longest length, etc.) can be, but is not limited to from about 5 nanometers (nm) to about 1,000 nm, for example, from about 5 nm to about 200 nm. The organic additive accounts for from about 0.001% to about 50% of the weight of the ink. This ink can be used to form a metal chalcogenide film. The ink may also be referred to herein as a “suspension,” “dispersion” or “particle-based solution,” and these terms will be used synonymously herein. The term “ink” also encompasses a liquid composed of at least one solvent, at least one dissolved metal salt, at least one dissolved source of chalcogenide and at least one organic additive. In this case, the ink can be considered a “pure solution” since there are no dispersed particles and everything in the ink is fully dissolved. Thus, the term “ink,” as used herein encompasses either a solution or dispersion of metal chalcogenides and organic additive(s) in a liquid medium.

The family of absorbers referred to as “kesterites” consists of Cu₂ZnSnS₄ (CZTS), as well as Cu₂ZnSnSe₄ (CZTSe) and more generally Cu₂ZnSn(S,Se)₄ (CZTSSe), with the S:Se ratio governing the band gap in the material. Besides tailoring the band gap using the S:Se ratio, substitution of Ge for Sn (i.e., Cu₂Zn(Sn,Ge)(S,Se)₄) can also be employed. The above formulas for kesterites represent the ideal stoichiometries. As described above, for photovoltaic applications, it is found that non-stoichiometric compositions yield higher conversion efficiency, with generally a copper poor and zinc rich composition yielding the highest efficiencies. When the term kesterite or CZTS is employed in the present description it is meant to refer to the full range of kesterite compositions based on Cu, Zn, Sn, Ge, Sn, S, Se, as well as including other common impurity atoms such as Na, K, Sb, Bi, Li. The term “CIGS,” as used herein refers to a material with the chalcopyrite structure of the formula CuInS₂, CuInSe₂, Cu(Ga,In)Se₂, CuIn(S,Se)₂, Cu(Ga,In)(S,Se)₂ and may also include other impurity atoms such as Na, K, Sb, Bi, Li, Ca, Sr, Ba and B.

The term “chalcogenides,” as used herein, refers to compounds that contain chalcogens such as S, Se and/or Te. In one exemplary embodiment, the chalcogens used in accordance with the present techniques are S and/or Se.

The present techniques relate to adding additives into a metal chalcogenide-containing liquid medium to improve grain structure and morphology of copper-based quaternary chalcogenide thin films prepared from such liquid, which leads to the enhancement of photovoltaic conversion efficiency of the devices developed from the films.

FIG. 1 is a diagram illustrating an exemplary methodology 100 for fabricating a chalcogenide film from additive-containing pure solution and particle-based routes. To begin the process, a precursor composition is prepared. The term “precursor” refers to the fact that the composition contains the elements needed to form the final film. However, until the composition is deposited and annealed (as described below) to enable formation of the desired crystal structure, the composition is only a precursor to the final film. As will be described in detail below, the precursor composition will be deposited onto a substrate, which after an annealing process will form the chalcogenide film. The precursor composition can be either a solution or a dispersion (i.e., a particle-based solution) containing dissolved components and/or solid particles, and as provided above is also referred to herein as an “ink.” Ideally the target during the precursor composition (ink) formation is a true solution with all of the precursors completely dissolved in a liquid medium, which will facilitate film deposition. However in practice, it is often the case that some or all of the metal chalcogenide precursors are not able to dissolve into any solvents. Thus, an alternative is to use a suspension/dispersion as an ink that contains all of the precursors (i.e., a particle-based ink).

Namely, in step 102, metal chalcogenides are contacted (i.e., mixed) in a liquid medium to form a solution or a dispersion (also referred to herein as a “metal chalcogenide-containing liquid medium”). According to an exemplary embodiment, the metal chalcogenides include a copper (Cu) chalcogenide, a first metal (M1) chalcogenide and a second (M2) chalcogenide. M1 and M2 each include an element selected from the group including silver (Ag), manganese (Mn), magnesium (Mg), iron (Fe), cobalt (Co), cadmium (Cd), nickel (Ni), chromium (Cr), zinc (Zn), tin (Sn), indium (In), gallium (Ga), aluminum (Al), and germanium (Ge). According to an exemplary embodiment, M1 is Sn and M2 is Zn.

Optionally, in step 104, an additional M3 chalcogenide or M3 salt is contacted with the liquid medium, wherein M3 includes an element selected from the group including, sodium (Na), potassium (K), lithium (Li), antimony (Sb), bismuth (Bi), calcium (Ca), strontium (Sr), barium (Ba), and boron (B).

Suitable Cu chalcogenides include, but are not limited to, Cu₂S, CuS, CuSe, Cu₂Se, Cu₂SnS₃, Cu₂SnSe₃, Cu₂Sn(S,Se)₃, Cu₂ZnSnS₄, Cu₂ZnSnSe₄, Cu₂ZnSn(S,Se)₄ and combinations including at least one of the foregoing metal chalcogenides. Suitable M1 chalcogenides include, but are not limited to, SnSe, SnS, SnSe₂, SnS₂, Cu₂SnS₃, Cu₂SnSe₃, Cu₂Sn(S,Se)₃, Cu₂ZnSnS₄, Cu₂ZnSnSe₄, Cu₂ZnSn(S,Se)₄ and combinations including at least one of the foregoing metal chalcogenides. Suitable M2 chalcogenides include, but are not limited to, ZnS, ZnSe, Cu₂ZnSnS₄, Cu₂ZnSnSe₄, Cu₂ZnSn(S,Se)₄ and combinations including at least one of the foregoing metal chalcogenides.

Suitable M3 chalcogenides or M3 salts include but are not limited to Sb₂S₃, Sb₂Se₃, Sb₂(S,Se)₃, Sb₂S₅, Na₂S, Na₂Se, Na₂(S,Se), K₂S, K₂Se, K₂(S,Se), Li₂S, Li₂Se, Li₂(S,Se), Bi₂S₃, Bi₂Se₃, Bi₂(S,Se)₃, ShCl₃, SbBr₃, SbI₃, antimony(III) acetate, antimony(III) tartrate, SbCl₅, SbBr₅, SbF₃, SbF₅, NaCl, NaBr, NaI, NaF, NaOH, sodium acetate, Na₂SO₄, NaNO₂, NaNO₃, Na₂SO₃, Na₂SeO₃, Na₂S₂O₃, KF, KCl, KBr, KI, KOH, potassium acetate, K₂SO₄, KNO₂, KNO₃, K₂SO₃, K₂S₂O₃ K₂SeO₃, LiF, LiCl, LiBr, LiI, LiOH, lithium acetate, Li₂SO₄, LiNO₃, LiNO₂, Li₂SO₃, Li₂S₂O₃, Li₂SeO₃, BiF₃, BiCl₃, BiBr₃, BiI₃, Bi(NO₃).5H₂O, bismuth(III) acetate, and bismuth(III) citrate.

According to an exemplary embodiment, the liquid medium is a solvent such as water or a non-aqueous liquid, the latter being either an organic or inorganic liquid. Preferably, the liquid medium is a solvent that can be substantially eliminated (e.g., greater than 90% of the solvent can be removed) by evaporation at a temperature lower than the decomposition temperature for the solvent. Suitable exemplary solvents that meet this criterion are provided below. For example, water (an inorganic solvent) can be evaporated at temperature of about 100° C. and ethanol (an organic solvent) evaporates at a temperature of greater than about 78° C. Suitable solvents include, but are not limited to, water, ammonium hydroxide, ammonium hydroxide-water mixtures, ammonium sulfide-ammonium hydroxide-water-mixtures, alcohols, ethers, glycols, aldehydes, ketones, alkanes, amines, dimethylsulfoxide (DMSO), cyclic compounds, halogenated organic compounds and combinations including at least one of the foregoing solvents.

The M3 chalcogenide or metal salt which is optionally added in step 104 may be added to the metal chalcogenide-containing liquid medium to improve the film formation and/or affect certain properties of the film. Suitable M3 metals were provided above. These M3 metals become incorporated into the metal chalcogenide-containing liquid. A small amount (e.g., from about 0.0001 percent by weight (% wt) to about 10% wt) of these metals may be added into the metal chalcogenide-containing liquid medium to improve the film formation or certain physical properties. For example, Na is a well known additive in photovoltaic films that is used to change the conductivity of the material. See, for example, A. Rockett, “The effect of Na in polycrystalline and epitaxial single-crystal CuIn₍₁₋ₓ₎Ga₍ₓ₎Se₂,” Thin Solid Films, 480-481, 2 (2005); H. Nukala, et al. “Synthesis of optimized CZTS thin films for photovoltaic absorber layers by sputtering from sulfide targets and sulfurization” Mater. Res. Soc. Symp. Proc. 1268-EE03-04 (2010), the contents of each of which are incorporated by reference herein.

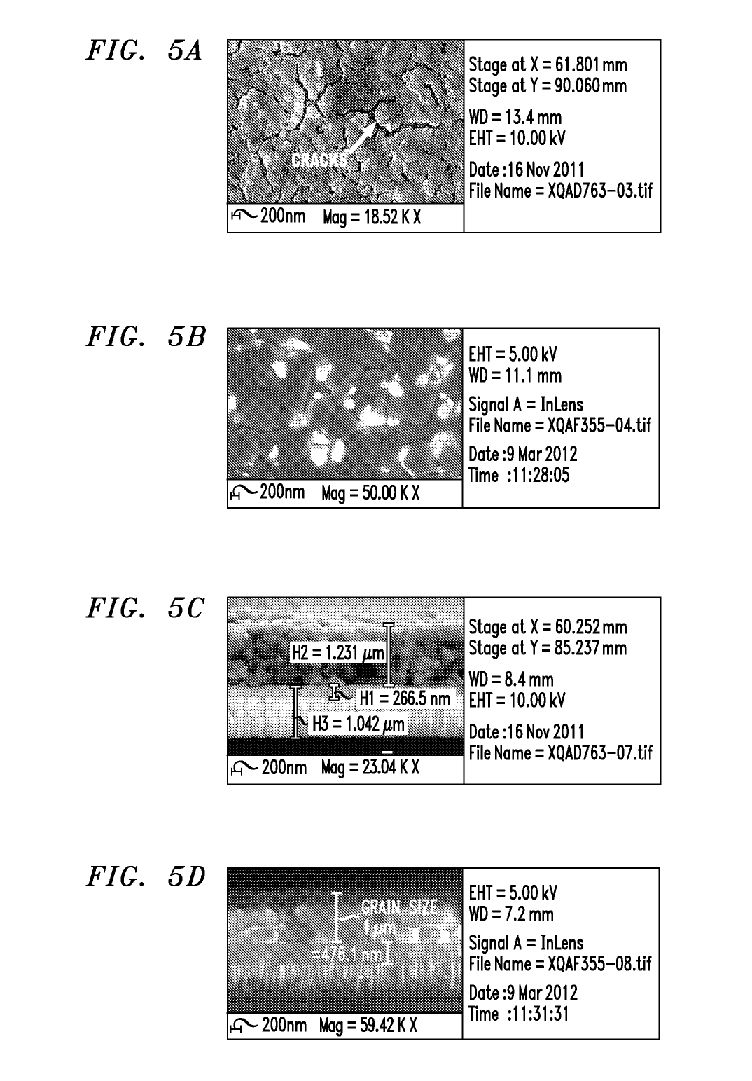

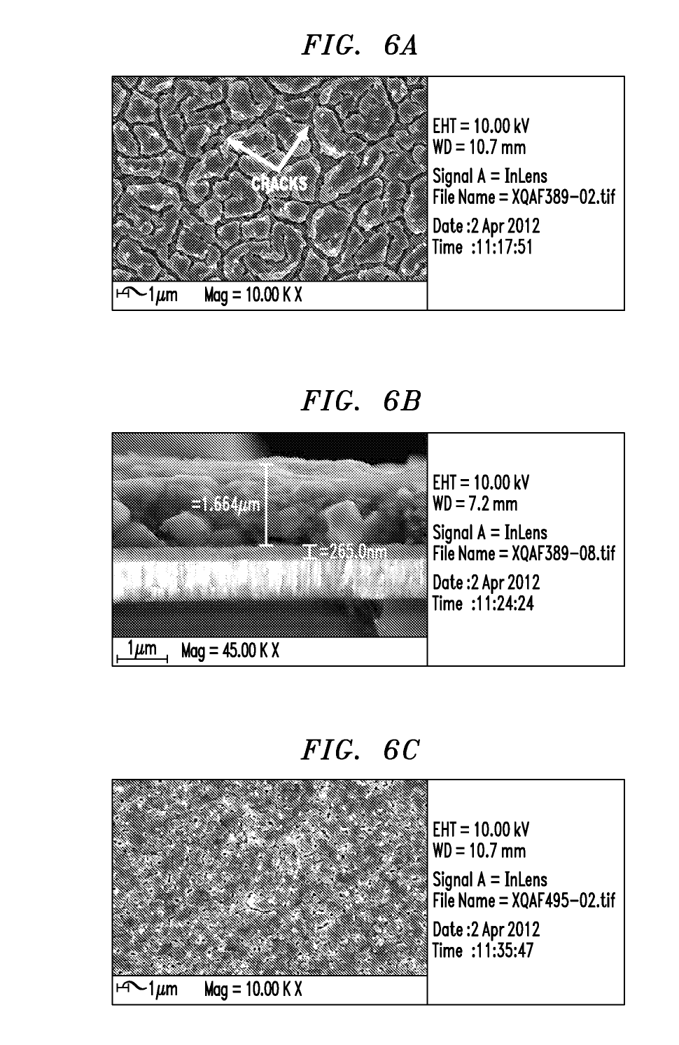

The term “improved grain size,” as used herein, refers to targeting grain sizes on the order of the absorber layer thickness (micrometer (μm)-length scale), which is desirable in order to minimize the photogenerated electron and hole recombination at the grain interfaces. Preferably, average gain size is from about 300 nm to about 100 μm. For example, average grain size is from about 500 nm to about 10 μm. For example, FIG. 5D (described below) shows the typical good grain size in the film made from urea-containing ink is on the order of the film thickness (about 1 μm)

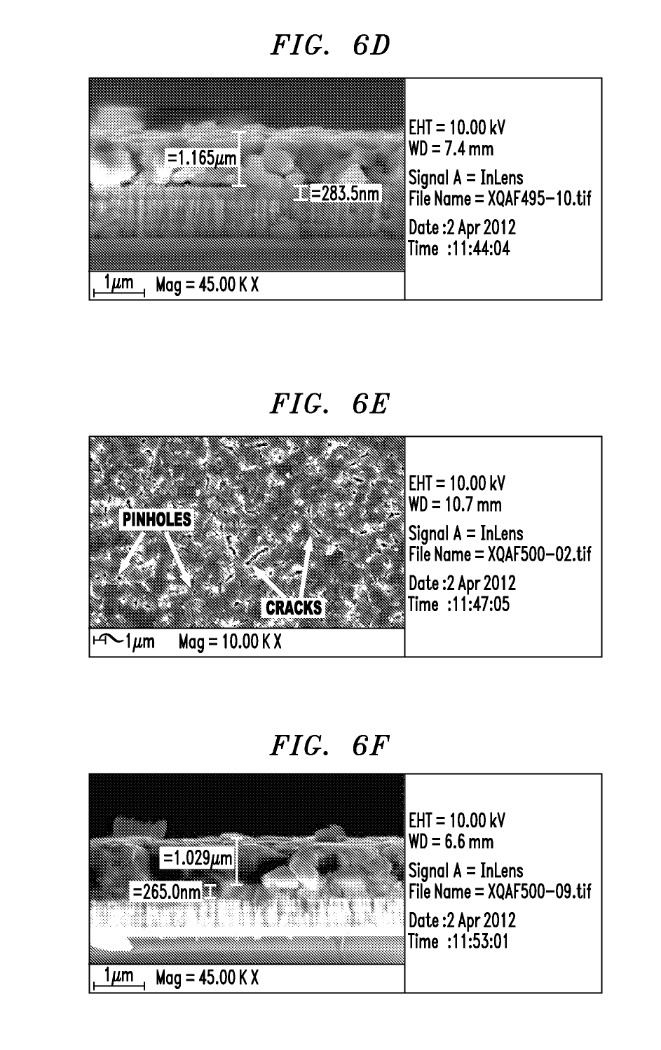

The term “improved film morphology” described herein refers to the film with less or free of cracks and pin holes. By way of example only, films prepared using the present techniques if not completely free of cracks and/or pinholes will have cracks with a length that is less than 5 μm and a width that is less than 1 μm, e.g., a length less than 1 μm and a width less than 500 nm, and pinholes having a diameter of less than 1 μm, for example, a diameter of less than 500 nm. Pinhole means a void that goes all the way from a top of the film to the back contact. For example, FIG. 6A (described below) shows the cracks in CZTS prepared without urea. Most of the cracks are longer than 10 μm and wider than 2 μm. FIG. 6E (described below) shows the cracks and pinholes in the film prepared from ink with urea and Na addition. The crack is shorter than 3 μm and narrower than 300 nm. The pinholes are smaller than 200 nm in diameter.

Next, in step 106, an organic additive(s) is/are contacted (mixed) with the metal chalcogenides in the liquid medium. According to an exemplary embodiment, the organic additive is a molecule of a form:

R1=CR2R3, (1)

wherein R1 is an element selected from group 16 of the periodic table of elements (i.e., oxygen (O), sulfur (S), selenium (Se), and tellurium (Te), C is carbon, and R2 and R3 each represent any element or functional group. R2 and R3 can be the same or different element/functional group. According to an exemplary embodiment, R2 and R3 are each primary amine groups.

By way of example only, suitable organic additives in accordance with Equation 1 include, but are not limited to, urea, thiourea and selenourea. Urea is preferred due to its abundance, low cost and non-toxicity. Urea can easily decompose to NH₃ and CO₂ in the presence of water at temperatures below 150° C. Urea is also very soluble in water (107.9 g/100 mL 20° C.) and many other solvents like alcohols, and therefore can be easily introduced into many solution-based processes. The present techniques are not limited to the use of a single organic additive. For instance, the solubility of urea in ethanol (50 g/L) is limited. Therefore another possible additive, such as thiourea, (35 g/L) (in addition to urea) is added to the liquid medium to reach the above-stated concentration (e.g., a combined concentration of greater than 70 g/L) of organic additive and thus achieve adequate grain growth in the film.

The organic additive(s) can be introduced into the metal chalcogenide-containing liquid medium (from step 102) in several different ways. For instance, the organic additive(s) can be first dissolved in a liquid medium to form an organic additive-containing liquid medium. The liquid medium can be a solvent. Suitable solvents were provided above. The organic additive-containing liquid medium can then be mixed with the chalcogenide-containing liquid medium under agitation, stirring and/or sonication. Alternatively, the solid state organic additive(s) can be added directly to the chalcogenide-containing liquid medium also under agitation, stirring and/or sonication.

Accordingly, the organic additive(s) should sufficiently dissolve in the liquid medium. Preferably, the solubility of the organic additive(s) in the liquid medium is from about 1 micromolar (μM) to about 100 molar (M), e.g., the solubility is from about 1 millimolar (mM) to about 10 M.

One characteristic of the additive used in this technique is that it is easy to be removed from the film materials upon gentle heating. Generally, it is thought that it is preferable to avoid the introduction of organic additives to solutions and slurries used for the deposition of metal chalcogenide films, because the additives are thought to leave residue of carbon or oxygen that can lead to inferior device performance. The organic additive(s) in the present techniques are therefore designed to be readily removed from the metal chalcogenides upon heat treatment (step 110) after solution deposition (step 108). The additives of choice are targeted to be chemicals that can decompose or evaporate upon gentle heat treatment, for example, at temperatures lower than about 300 degrees Celsius (° C.), more preferably at a temperature of from about 30° C. to about 150° C.

Also, in order to facilitate removal of the organic additive(s) upon annealing, the organic additive(s) is preferably added after the metal chalcogen bonding has formed (either particle or ionic species) to avoid strong coordination between metal ions and additives. Namely, step 102 serves to mix/bond the metal chalcogenides within the liquid medium. Adding the organic additive(s) in step 106, after this metal chalcogen bonding takes place, will help ensure that the organic additive(s) are weakly or moderately attached to the surface of the metal chalcogenide particles, particle agglomerates or metal compounds (for example, the binding energy is less than 150 kJ/mol, e.g., the binding energy is less than 50 kJ/mol); therefore the organic additive(s) can be removed without leaving chemical residues upon gentle heat-treatment, preferably at temperatures lower than 300° C., more preferably, from about 30° C. to about 150° C.

The precursor composition now formed may be used in the fabrication of a chalcogenide film as described in detail below. As provided above, the precursor composition can be a solution, or a dispersion (the precursor composition solution or dispersion also referred to herein as an ink). Accordingly, based on the above description, the precursor composition will contain at least one organic additive and metal chalcogenides in a liquid medium. The metal chalcogenides include 1) a Cu chalcogenide, 2) an M1 chalcogenide and 3) an M2 chalcogenide. M1 and M2 each include an element selected from: Ag, Mn, Mg, Fe, Co, Cd, Ni, Cr, Zn, Sn, In, Ga, Al, and Ge. Further as provided above, optionally, an additional M3 chalcogenide or M3 salt is contacted with the liquid medium, wherein M3 is an element selected from the group including: Na, K, Li, Sb, Bi, Ca, Sr, Ba, and B.

According to an exemplary embodiment, a concentration of the metal chalcogenide species in the precursor composition is from about 1 μM to about 100M, e.g., from about 10 μM to about 1M. In this example, the fluid medium accounts for from about 10 weight percent (wt %) to about 99 wt % of the precursor composition. Further, in this example, a concentration of the organic additive(s) in the precursor composition varies from about 1 micromolar to the solubility limit of the additive in certain solvents at a given temperature. For example, the upper limit of the urea concentration in water at 20° C. is 17.84 M. According to an exemplary embodiment, the concentration of the organic additive(s) in the precursor composition is from about 1 μM to about 100M, e.g., from about 10 μM to about 10M.

The process for using the precursor composition to form a chalcogenide film is now described. In step 108, the precursor composition (i.e., solution or dispersion/ink) is deposited onto a substrate to form a layer. By way of example only, suitable substrates include, but are not limited to, a metal foil substrate, aluminum foil coated with a layer of molybdenum, a glass substrate with conductive coating, a ceramic substrate with conductive coating and/or a polymer substrate with a conductive coating. The present techniques may be employed to form an absorber layer of a photovoltaic device (see below). The conductive coating/layer or substrate can, in that instance, serve as an electrode of the device. In one embodiment the substrate is metal or alloy foil containing as non-limiting examples molybdenum, aluminum, titanium, iron, copper, tungsten, steel or combinations thereof. In another embodiment the metal or alloy foil is coated with an ion diffusion barrier and/or an insulating layer succeeded by a conductive layer. In another embodiment the substrate is polymeric foil with a metallic or other conductive layer (e.g., transparent conductive oxide, carbon) deposited on the top of it. In one preferred embodiment, regardless of the nature of the underlying substrate material or materials, the surface contacting the liquid layer contains molybdenum.

Suitable processes for depositing the precursor composition onto the substrate include, but are not limited to spin-coating, dip-coating, doctor blading, curtain coating, slide coating, spraying, slit casting, meniscus coating, screen printing, ink jet printing, pad printing, flexographic printing and gravure printing. After a liquid layer of the precursor composition is deposited on the surface of the substrate, the process of drying the film and removing some part of the excess chalcogen may be initiated by evaporation, by means of exposure to ambient or controlled atmosphere or vacuum that may be accompanied with a thermal treatment, referred to as preliminary anneal, to fabricate a substrate coated with a hybrid precursor including discrete particles and surrounding media. This surrounding media is formed by solidification of the dissolved component. The process of depositing the precursor composition onto the substrate and of drying the film and removing some part of the excess chalcogen may be repeated multiple times to increase film thickness (i.e., to achieve a desired thickness) before proceeding to step 110.

Next, in step 110, the layer (deposited in step 108) is annealed (also referred to as a heat treatment) at a temperature, pressure and for a duration sufficient to form the chalcogenide film. Namely, the metal chalcogenide precursor layer is heated to a temperature sufficient to induce reaction/recrystallization and grain growth among the metal chalcogenide species therein to form a nominally single-phase film with an average grain size with at least one dimension greater than 50 nm, e.g., greater than 200 nm, with the desired composition.

According to an exemplary embodiment, the heat treatment involves heating the film to a temperature of from about 200° C. to about 800° C., for example, from about 300° C. to about 700° C., e.g., from about 450° C. to about 650° C., at a pressure of from about 1 μPa(scal) to about 1×10⁶ Pa(scal), for a duration of from about 10 seconds to about 120 minutes, e.g., from about 2 minutes to about 60 minutes. The step of heat treating is preferably carried out in an atmosphere including at least one of nitrogen, argon, helium, forming gas, and a mixture containing at least one of the foregoing gases. This atmosphere can further include vapors of at least one of S, Se, Sn and a compound containing S, Se and/or Sn (e.g., H₂S, H₂Se, SnS, SnSe, SnS₂ or SnSe₂). The ratio of S and Se sources in the vapor can be selected to impact the final S:Se ratio in the final film. The film produced in this manner preferably contains at least 80% by mass of the targeted compound, more preferably at least 90% by mass of the targeted compound and even more preferably at least 95% by mass of the targeted compound. The targeted compound is, for example, the CZTS, CZTSe or CZTSSe kesterite compound of the formula provided above.

The anneal can be carried out by any technique known to one of skill in the art, including but not limited to, furnace, hot plate, infrared or visible radiation and convective (e.g., laser, lamp furnace, rapid thermal anneal unit, resistive heating of the substrate, heated gas stream, flame burner, electric arc and plasma jet). The intimate contact between the two components of the hybrid precursor (particle component and solidified dissolved component) for most embodiments enables limiting the anneal duration to less than 60 minutes (as provided above).

Other techniques for fabricating kesterite films are described in U.S. patent application Ser. No. 13/207,269, filed by Bag et al., entitled “Capping Layers for Improved Crystallization,” and in U.S. patent application Ser. No. 13/207,187, filed by Mitzi et al., entitled “Particle-Based Precursor Formation Method and Photovoltaic Device Thereof,” and in U.S. patent application Ser. No. 13/207,248, filed by Mitzi et al., entitled “Process for Preparation of Elemental Chalcogen Solutions and Method of Employing Said Solutions in Preparation of Kesterite films,” (hereinafter “U.S. patent application Ser. No. 13/207,248”) and in U.S. Patent Application Publication Number 2011/0097496, filed by Mitzi et al., entitled “Aqueous-Based Method of Forming Semiconductor Film and Photovoltaic Device Including the Film,” the entire contents of each of which are incorporated by reference herein.

The result is a chalcogenide film having been formed on the substrate. The obtained film on the substrate may then be used for the desired application, such as, optical, electrical, anti-friction, bactericidal, catalytic, photo-catalytic, electromagnetic shielding, wear-resistance, and diffusion barrier. As will be described in detail below, in one exemplary implementation, the above-described process is used to fabricate the absorber layer of a photovoltaic device, i.e., wherein the chalcogenide film serves as the absorber layer.

In one exemplary embodiment, the chalcogenide film formed has a formula:

Cu₂₋ₓM1_{1+y}M2₁₊ₚ(S_{1-z}Se_{z})_{4+q}, (2)

wherein 0≦x≦1; —1≦y≦1; —1≦p≦1; 0≦z≦1; —1≦q≦1. Thus, the present techniques can be used to fabricate both CIGS (chalcopyrite) and CZTS (kesterite) chalcogenide films. For kesterite materials additives and non-stoichiometry are often desired. For example, in one exemplary embodiment, M1 and M2 are Zn and Sn, respectively, and the chalcogenide film formed has a formula:

Cu₂₋ₓZn_{1+y}Sn₁₊ₚ(S_{1-z}Se_{z})_{4+q}, (3)

wherein 0≦x≦1; −1≦y≦1; −1≦p≦1; 0≦z≦1; and −1≦q≦1, for example, wherein x, y, z, p and q are: 0≦x≦0.5; −0.5≦y≦0.5; −0.5≦p≦0.5; 0≦z 51; and −0.5≦q≦0.5, respectively.

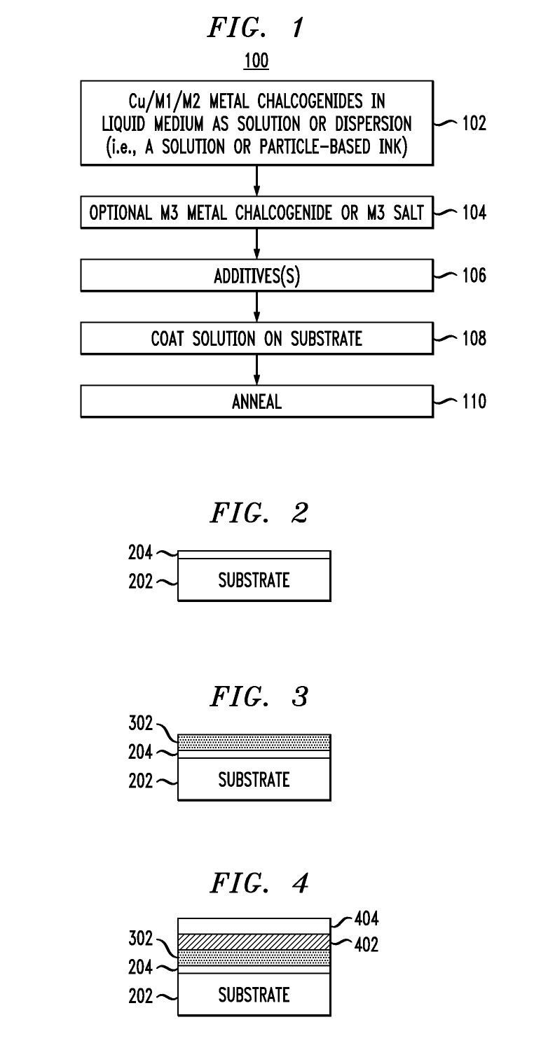

The implementation of the present techniques for the fabrication of a photovoltaic device is now described by way of reference to FIGS. 2-4. To begin the photovoltaic device fabrication process, a substrate 202 is provided. See FIG. 2. As highlighted above, suitable substrates include, but are not limited to, a metal foil substrate, a glass substrate, a ceramic substrate, aluminum foil coated with a (conductive) layer of molybdenum, a polymer substrate, and any combination thereof. Further, as described above, if the substrate material itself is not inherently conducting then the substrate is preferably coated with a conductive coating/layer. This situation is depicted in FIG. 2, wherein the substrate 202 has been coated with a layer 204 of conductive material. Suitable conductive materials for forming layer 204 include, but are not limited to, molybdenum (Mo), which may be coated on the substrate 202 using sputtering or evaporation.

Next, as illustrated in FIG. 3, a chalcogenide film 302 is formed on the substrate 202. In the particular example shown in FIG. 3, the substrate 202 is coated with the conductive layer 204 and the chalcogenide film 302 is formed on the conductive layer 204. Chalcogenide layer 302 may be formed on the substrate 202 using the techniques described in conjunction with the description of methodology 100 of FIG. 1, above. The chalcogenide film 302 will serve as an absorber layer of the device.

An n-type semiconducting layer 402 is then formed on the kesterite layer 302. According to an exemplary embodiment, the n-type semiconducting layer 402 is formed from zinc sulfide (ZnS), cadmium sulfide (CdS), indium sulfide (InS or In₂S₃), oxides thereof and/or selenides thereof, which is deposited on the kesterite layer 302 using for example vacuum evaporation, chemical bath deposition, electrochemical deposition, atomic layer deposition (ALD), and Successive Ionic Layer Adsorption And Reaction (SILAR). Next, a top electrode 404 is formed on the n-type semiconducting layer 402. As highlighted above, the substrate 202 (if inherently conducting) or the layer 204 of conductive material serves as a bottom electrode of the device. Top electrode 404 is formed from a transparent conductive material, such as doped zinc oxide (ZnO), indium-tin-oxide (ITO), doped tin oxide or carbon nanotubes. The process for forming an electrode from these materials would be apparent to one of skill in the art and thus is not described further herein.

According to the present teachings, the addition of the above-described organic additive(s) (such as urea) is considered to be primarily responsible for grain structures and film morphology, however, additionally added metal species, such as Na species can also further fine-tune the grain structures and film morphology.

For example, FIGS. 5A-D show the impact of urea and Na on the grains structures and film morphology. Specifically, FIGS. 5A-D are scanning electron micrograph images. The image shown in FIG. 5A is a top view of a sample metal chalcogenide film prepared from ink containing no urea but about 15 wt % of ammonium sulfide as a source of sulfur to assist CZTS crystallization. The image shown in FIG. 5C is a cross-sectional view of the same film as in FIG. 5A. The image shown in FIG. 5B is a top view of a sample metal chalcogenide film prepared from ink containing 0.2M urea and 0.5 at. % NaF. FIG. 5D is a cross-sectional view of the same film as in FIG. 5B.

Compared to the film prepared from an ink without urea and Na (see FIGS. 5A and 5C), urea and Na greatly promoted the growth of CZTS grains and fixed the surface cracks (see FIGS. 5B and 5D). In order to further distinguish the effect of urea and Na, inks containing only Na, only urea and both urea and Na as additive(s) were used to develop CZTS thin film and photovoltaic devices. See SEM images in FIGS. 6A-6F.

Specifically, FIG. 6A is a top view of a sample metal chalcogenide film prepared from ink using only Na as additive. FIG. 6B is a cross-sectional view of the same film as in FIG. 6A. It is clear from FIGS. 6A and 6B that the film was cracked and the grain size of such film was small. FIG. 6C is a top view of a sample metal chalcogenide film prepared from ink using only urea as additive. FIG. 6D is a cross-sectional view of the same film as in FIG. 6C. The surface of the film is much less cracked and the grains are much larger than the film shown in FIGS. 6A and 6B. FIG. 6E is a top view of a sample metal chalcogenide film prepared from ink using both urea and Na as additives. FIG. 6F is a cross-sectional view of the same film as in FIG. 6E. Thus, when both urea and Na were added as additives, the surface is even less cracked and the grain structures are better than the film developed from urea only ink.

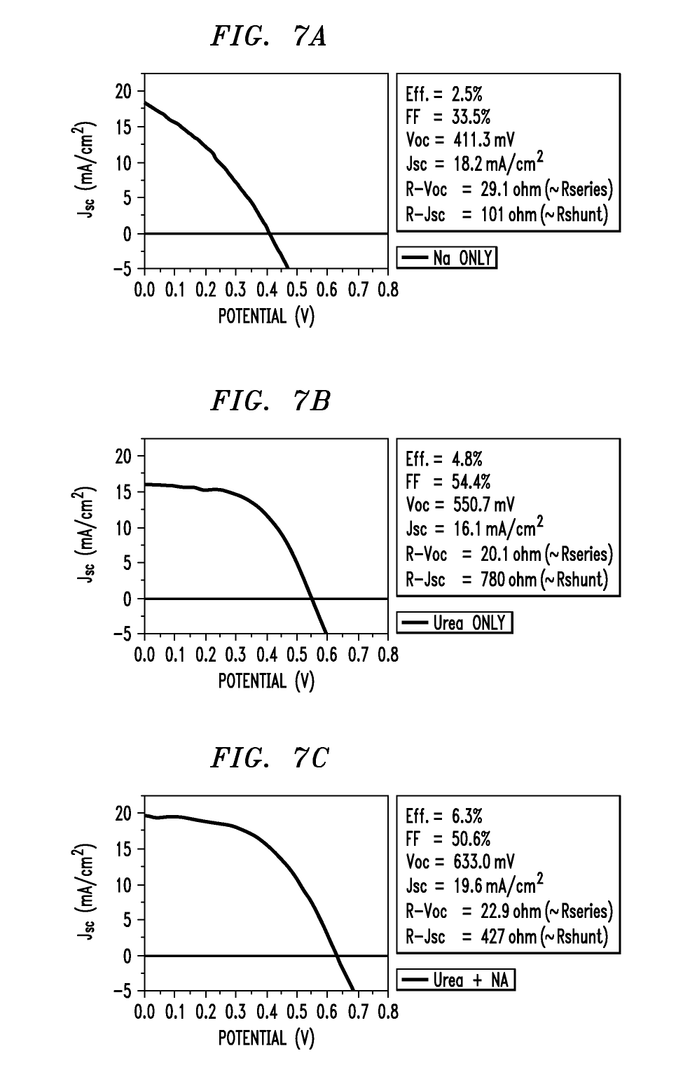

As a result, the performance of the photovoltaic devices developed from the above mentioned films are highly related to the grain structures and film morphology. See FIGS. 7A-C. Specifically, FIG. 7A is a graph illustrating electrical characteristics of a metal chalcogenide film prepared using only Na as an additive, FIG. 7B is a graph illustrating electrical characteristics of a metal chalcogenide film prepared using only urea as an additive, and FIG. 7C is a graph illustrating electrical characteristics of a metal chalcogenide film prepared using both Na and urea as additives.

The device from ink using only Na as an additive showed quite low efficiency of 2.5% (FIG. 7A), which may be due to the small grains and cracked surface shown in FIGS. 6A and 6B. While with improved grains and surface morphology, the device prepared from ink using only urea as an additive showed significantly improved efficiency of 4.8% (FIG. 7B). Furthermore an ink containing both urea and Na yielded a device with conversion efficiency of 6.2%, which reflects the relatively good grain structures and film morphology (FIG. 7C). This demonstrates that urea is the primary additive to promote the grain growth and film morphology and the Na effect is secondary. Notwithstanding this, the present techniques encompass situations wherein both urea and Na are added to the film.

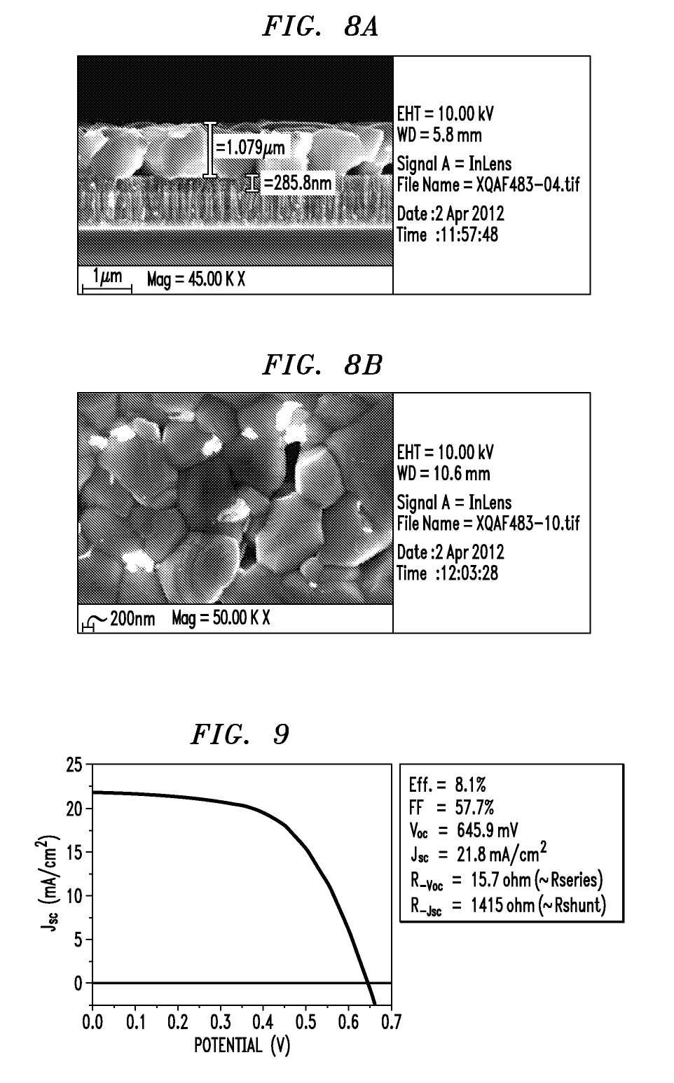

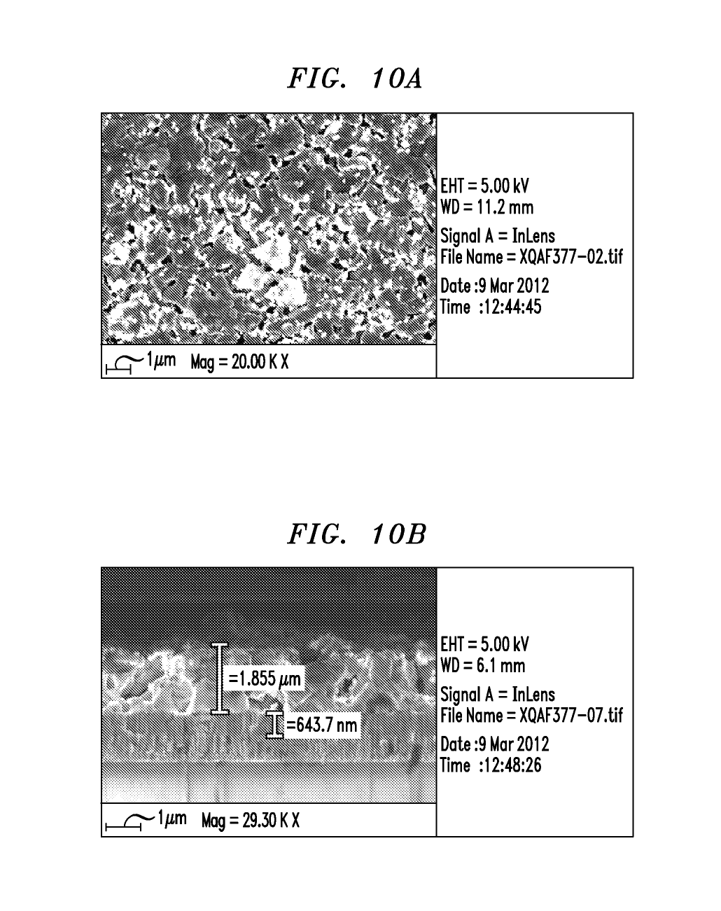

Advantageously, use of the present techniques has yielded devices with energy conversion efficiencies of 8.1% or greater with urea only inks. See examples below. For instance, FIGS. 8A and 8B (described below) show SEM images of the film prepared from a urea-only ink and FIG. 9 (described below) illustrates the characteristics of a photovoltaic device based on this film.

The present techniques are further described by way of reference to the following non-limiting examples

### Example 1

### CZTS Device Absorber Layer Preparation Using Urea as Additive

1. The preparation of precursor ink for thin film deposition: An aqueous ink was prepared by first dissolving 1.015 g of copper(II) chloride (CuCl₂, 99.99%, anhydrous from Sigma-Aldrich), 0.600 g of zinc chloride (ZnCl₂, 99.99%, anhydrous, from Alfa Aesar) and 0.519 mL of tin (IV) chloride (SnCl₄, 99.995%, anhydrous from Sigma-Aldrich) into 15 mL of de-ionized water. This solution was then slowly added into a mixture of 5 mL ammonium sulfide (40-44% wt. in water, from Strem chemicals Inc.) and 5 mL deionized water under vigorous stirring. After the mixing was finished, another 5 mL of ammonium sulfide (40-44% wt. in water, from Strem chemicals Inc.) and 5 mL of deionized water were added into the mixture under stirring. The mixture was then stirred for 10 minutes and subjected to ultrasound for 60 minutes. Then the mixture was stirred for another 2 hours. A brownish well-mixed slurry was formed. The solid part of the slurry (a mixture of metal sulfides) can be isolated by centrifugation at 3,500 rpm/min for 15 minutes. The solid part was then redispered into deionized water and again separated from the mixture using centrifugation. The washing and centrifuge process was repeated twice; Sometimes, 1-2 mL of ammonium sulfide (40-44% wt. in water, from Strem chemicals Inc.) was used to help in the separation. After washing, the solid part was redispersed into deionized water by stirring to form a final volume of 24 mL of metal sulfide slurry. This constitutes the formation of metal chalcogenides in liquid medium (as per step 102 of methodology 100 (see description of FIG. 1, above). Optionally, NaF can be added at a concentration of from 0 at. % to 10 at. %, preferably from 0 at. % to 1 at. %. This constitutes step 104 in FIG. 1 (optional M3 metal chalcogenide or M3 salt).

The final ink for film deposition was prepared by mixing 6 mL of the cleaned metal sulfides slurry, 2 mL of 2M urea aqueous solution (BioReagent from Sigma-Aldrich) and 1 mL of deionized water under vigorous stirring (as per step 106 of methodology 100 (see description of FIG. 1, above)). The ink was dispersed using ultrasound for 30 min and then stirred overnight before deposition. The ink preparation was performed in a nitrogen filled glovebox.

2. Thin Film Development:

The ink was deposited on a 1×1 inch or 2×2 inch (2-mm-thick) Mo-coated soda lime glass using spin coating in a nitrogen-filled glovebox (as per step 108 of methodology 100 (see description of FIG. 1, above). For a 2×2 inch substrate, 300 μl of ink was spread on the substrate, followed by a spin-coating recipe of 200 rpm 2 seconds, 800 rpm for 45 seconds and 1,200 rpm for 3 seconds. The film was completely dried after spin coating. Then the film was annealed at 350° C. for 2 minutes, followed by cooling to room temperature. This procedure was repeated 10 times in order to build sufficient film thickness. After the final layer was deposited, the film was heated at 650° C. for 15 minutes in the presence of 10 mg of S; optionally, SnS can be also added during annealing, with the amount of added SnS varying from 1 μg to 1 g, preferably, from 10 μg to 100 mg (as per step 110 of methodology 100 (see description of FIG. 1, above). Then the film was slowly cooled down to room temperature.

The film morphology was investigated by scanning electron microscopy (SEM). See FIGS. 8A and 8B. Specifically, FIGS. 8A and 8B are scanning electron micrograph images. The image shown in FIG. 8A is a cross-sectional view of a sample metal chalcogenide film prepared according to Example 1. FIG. 8B is a top view of the sample from FIG. 8A. The photovoltaic conversion efficiency (8.1%) of the device developed from such film is shown in FIG. 9.

### Example 2

### CZTSSe Device Absorber Layer Preparation Using Urea as Additive

1. The preparation of precursor ink for thin film deposition: An aqueous ink was prepared by first dissolving 1.015 g of copper(II) chloride (CuCl₂, 99.99%, anhydrous from Sigma-Aldrich), 0.667 g of zinc chloride (ZnCl₂, 99.99%, anhydrous, from Alfa Aesar) and 0.519 mL of tin (IV) chloride (SnCl₄, 99.995%, anhydrous from Sigma-Aldrich) into 15 mL of deionized water. This solution was then slowly added into a mixture of 5 mL ammonium sulfide (40-44% wt. in water, from Strem chemicals Inc.) and 5 mL deionized water under vigorous stirring. After the mixing was finished, another 5 mL of ammonium sulfide (40-44% wt. in water, from Strem chemicals Inc.) and 5 mL of deionized water were added into the mixture under stirring. The mixture was then stirred for 10 min and subjected to ultrasound for 60 minutes. Then the mixture was stirred for another 2 hours. A brownish well-mixed slurry was formed. The solid part of the slurry (a mixture of metal sulfides) can be isolated by centrifugation at 3,500 rpm/min for 15 minutes. The solid part was then redispered into deionized water and again separated from the mixture using centrifugation. The washing and centrifuge process was repeated twice; Sometimes, 1-2 mL of ammonium sulfide (40-44% wt. in water, from Strem chemicals Inc.) was used to help in the separation. After washing, the solid part was redispersed into deionized water by stirring to form a final volume of 24 mL of metal sulfide slurry. Optionally, NaF can also be added to the slurry at a concentration of from 0 at. % to 10 at. %, preferably from 0 at. % to 1 at. %.

The final ink for film deposition was prepared by mixing 7 mL of the cleaned metal sulfides slurry, 2 mL of 1M urea aqueous solution (BioReagent from Sigma-Aldrich) under vigorous stirring. The ink was dispersed using ultrasound for 30 minutes and then stirred overnight before deposition. The ink preparation was performed in a nitrogen-filled glovebox.

2. Thin Film Development:

The ink was deposited on a 1×1 inch or 2×2 inch (2-mm-thick) Mo-coated soda lime glass using spin coating in a nitrogen-filled glovebox. For a 2×2 inch substrate, 300 μL of ink was spread on the substrate, followed by a spin-coating recipe of 200 rpm for 2 seconds, 800 rpm for 45 seconds and 1,200 rpm for 3 seconds. The film was completely dried after spin coating. Then the film was annealed at 350° C. for 2 minutes, followed by cooling to room temperature. This procedure was repeated 11 times in order to build sufficient film thickness. After the final layer was deposited, the film was heated at 650° C. for 20 minutes in the presence of 20 mg Se pellet creating a CZTSSe film; optionally, SnSe can be also added during annealing, with the amount of added SnSe varying from 1 μg to 1 g, preferably, from 10 μg to 100 mg. Then the film was slowly cooled down to room temperature. For comparison, a pure sulfide (CZTS) film was also prepared by heating the film at 650° C. for 20 minutes in the presence of 10 mg S flake; optionally, SnS can be also added during annealing, with the amount of added SnS varying from 1 μg to 1 g, preferably, from 10 μg to 100 mg.

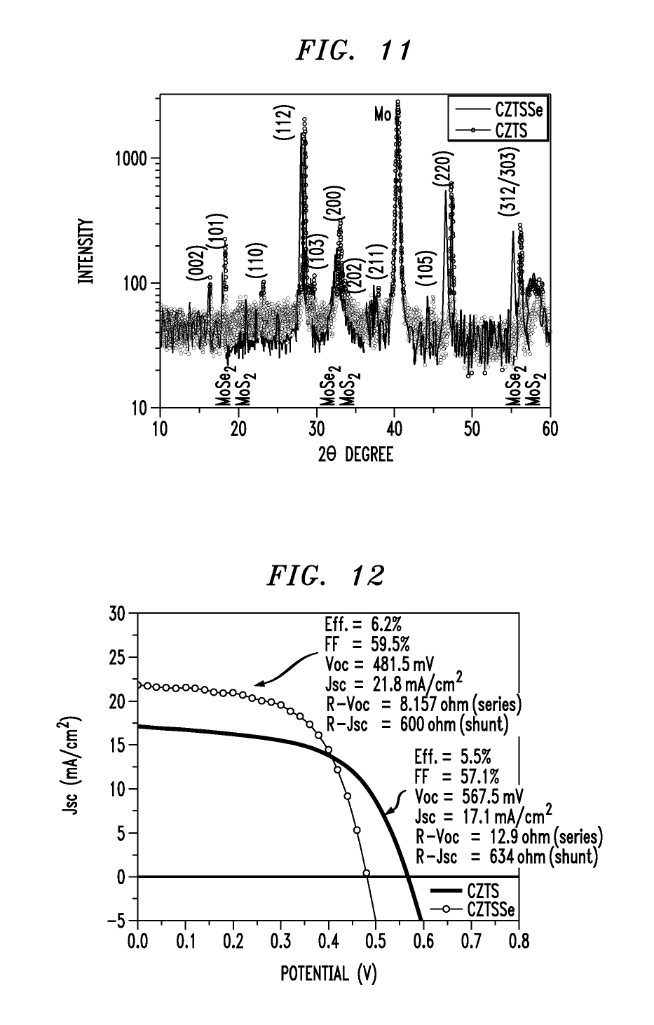

The film morphology was investigated by scanning electron microscopy (SEM). See FIGS. 10A and 10B. Specifically, FIGS. 10A and 10B are scanning electron micrograph images. The image shown in FIG. 10A is a top view of a sample CZTSSe film prepared according to Example 2. The image shown in FIG. 10B is a cross-sectional view of the film of FIG. 10A.

The powder X-ray diffraction patterns of CZTSSe and CZTS film showed the kesterite phase of both materials. See FIG. 11. The photovoltaic conversion efficiency of the CZTSSe and CZTS devices developed from such film is shown in FIG. 12. Clearly evident in the device results is the shift in open circuit voltage and short circuit current, demonstrating the substitution of Se for S in the absorber layer.

### Example 3

### CZTS Device Absorber Layer Preparation Using Thiourea as Additive

1. The preparation of precursor ink for thin film deposition: An aqueous ink was prepared by first dissolving 1.015 g of copper(II) chloride (CuCl₂, 99.99%, anhydrous from Alfa Aesar), 0.667 g of zinc chloride (ZnCl₂, 99.99%, anhydrous, from Alfa Aesar) and 0.591 mL of tin (IV) chloride (SnCl₄, 99.995%, anhydrous from Sigma-Aldrich) into 15 mL of deionized water. This solution was then slowly added into a mixture of 5 mL ammonium sulfide (40-44% wt. in water, from Strem chemicals Inc.) and 5 mL deionized water under vigorous stirring. After the mixing was finished, another 5 mL of ammonium sulfide (40-44% wt. in water, from Strem chemicals Inc.) and 5 mL of deionized water were added into the mixture under stirring. Then the mixture was stirred for 10 minutes and subjected to ultrasound for 60 minutes. The mixture was stirred for another 2 hours. A brownish well-mixed slurry was formed and continued to stir overnight. Then the solid part of slurry (a mixture of metal sulfides) was separated by centrifugation at 3,500 rpm/min for 15 minutes. The solid part was redispered into deionized water and separated from the mixture using centrifugation. The washing and centrifugation process was repeated twice; Sometimes, 1-2 mL of ammonium sulfide (40-44% wt. in water, from Strem chemicals Inc.) was used to help in the separation process. After washing, the solid part was redispersed into deionized water by stirring, forming a final volume of 24 mL of metal sulfide slurry. Optionally, NaF can also be added at a concentration of from 0 at. % to 10 at. %, preferably from 0 at. % to 1 at. %.

The final ink for film deposition was prepared by mixing 4 mL of the cleaned metal sulfides slurry, 1 mL of 1M thiourea aqueous solution under vigorous stirring. Sometimes, the ink was dispersed with the help of ultrasound for 30 min. The ink preparation was performed in a nitrogen-filled glovebox.

2. Thin Film Development:

The ink was deposited on a 1×1 inch or 2×2 inch (2-mm-thick) Mo-coated soda lime glass using spin coating in a nitrogen-filled glovebox. For a 2×2 inch substrate, 300 μL of ink was spread on the substrate, followed by a spin-coating recipe of 200 rpm for 2 seconds, 800 rpm for 45 seconds and 1,200 rpm for 3 seconds. The film was completely dried after spin-coating. Then the film was annealed at 350° C. for 2 minutes, followed by cooling to room temperature. This procedure was repeated 11 times in order to build sufficient film thickness. After the final layer was deposited, the film was heated at 650° C. for 20 minutes in the presence of 10 mg of S; optionally, SnS can be also added during annealing, with the amount of added SnS varying from 1 pg to 1 g, preferably, from 10 μg to 100 mg. Then the film was slowly cooled down to room temperature.

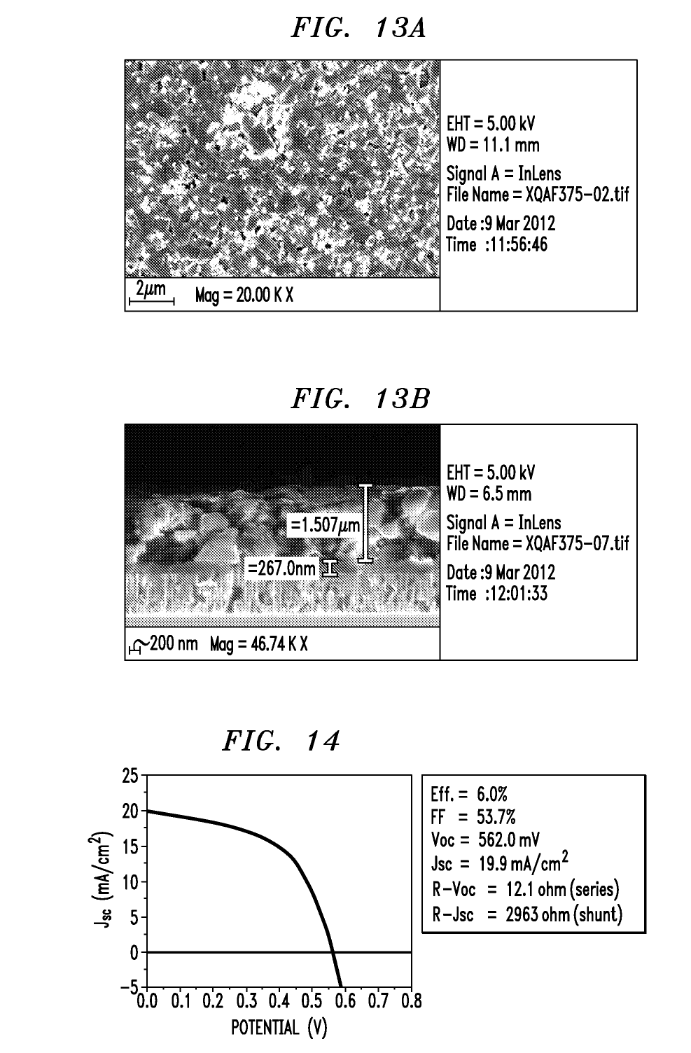

The film morphology was investigated by scanning electron microscopy (SEM). See FIGS. 13A and B. Specifically, FIGS. 13A and B are scanning electron micrograph images. The image shown in FIG. 13A is a top view of a sample metal chalcogenide film prepared according to Example 3. The image shown in FIG. 13B is a cross-sectional view of the film of FIG. 13A. The photovoltaic conversion efficiency of the device developed from such film is shown in FIG. 14.

Although illustrative embodiments of the present invention have been described herein, it is to be understood that the invention is not limited to those precise embodiments, and that various other changes and modifications may be made by one skilled in the art without departing from the scope of the invention.

What is claimed is:

1. A method of forming a chalcogenide film, comprising the steps of:
contacting metal chalcogenides in a liquid medium to form a solution or a dispersion, wherein the metal chalcogenides comprise a Cu chalcogenide, an M1 chalcogenide and an M2 chalcogenide, and wherein M1 and M2 each comprise an element selected from the group consisting of: Ag, Mn, Mg, Fe, Co, Cd, Ni, Cr, Zn, Sn, In, Ga, Al, and Ge;
contacting at least one organic additive with the metal chalcogenides in the liquid medium;
depositing the solution or the dispersion onto a substrate to form a layer; and
annealing the layer at a temperature, pressure and for a duration sufficient to form the chalcogenide film.

2. The method of claim 1, further comprising the step of:
contacting an M3 chalcogenide or an M3 salt with the liquid medium, wherein M3 comprises an element selected from the group consisting of: Na, K, Li, Sb, Bi, Ca, Sr, Ba, and B.

3. The method of claim 1, wherein the chalcogenide film is a copper-based quaternary chalcogenide film having a formula:
Cu₂₋ₓM1_{1+y}M2₁₊ₚ(S_{1-z}Se_{z})_{4+q},
wherein 0≦x≦1; −1≦y≦1; −1≦p≦1; 0≦z≦1; −1≦q≦1.

4. The method of claim 1, wherein the chalcogenide film has a formula:
C₂₋ₓZn_{1+y}Sn₁₊ₚ(S_{1-z}Se_{z})_{4+q},
wherein 0≦x≦1; −1≦y≦1; −1≦p≦1; 0≦z≦1; and −1≦q≦1.

5. The method of claim 4, wherein x, y, p, z and q are: 0≦x≦0.5; −0.5≦y≦0.5; −0.5≦p≦0.5 0≦z≦1; and −0.5−q≦0.5, respectively.

6. The method of claim 1, wherein the at least one organic additive is a molecule of a form R1=CR2R3, wherein R1 is an element selected from the group consisting of: O, S, Se, Te, and wherein R2 and R3 each comprise a primary amine group.

7. The method of claim 1, wherein the at least one organic additive is selected from the group consisting of urea, thiourea and selenourea.

8. The method of claim 1, wherein the at least one organic additive is urea.

9. The method of claim 1, wherein the at least one organic additive decomposes at a temperature of less than or equal to about 150° C.

10. The method of claim 1, wherein the at least one organic additive has a solubility of from about 1 μM to about 100M in the liquid medium.

11. The method of claim 1, wherein the Cu chalcogenide is selected from the group consisting of: Cu₂S, CuS, CuSe, Cu₂Se, Cu₂SnS₃, Cu₂SnSe₃, Cu₂Sn(S,Se)₃, Cu₂ZnSnS₄, Cu₂ZnSnSe₄, Cu₂ZnSn(S,Se)₄ and combinations comprising at least one of the foregoing metal chalcogenides.

12. The method of claim 1, wherein the M1 chalcogenide is selected from the group consisting of: SnSe, SnS, SnSe₂, SnS₂ Cu₂SnS₃, Cu₂SnSe₃, Cu₂Sn(S,Se)₃, Cu₂ZnSnS₄, Cu₂ZnSnSe₄, Cu₂ZnSn(S,Se)₄ and combinations comprising at least one of the foregoing metal chalcogenides.

13. The method of claim 1, wherein the M2 chalcogenide is selected from the group consisting of: ZnS, ZnSe, Cu₂ZnSnS₄, Cu₂ZnSnSe₄, Cu₂ZnSn(S,Se)₄ and combinations comprising at least one of the foregoing metal chalcogenides.

14. The method of claim 2, wherein the M3 chalcogenide or the M3 salt is selected from the group consisting of: Sb₂S₃, Sb₂Se₃, Sb₂(S,Se)₃, Sb₂S₅, Na₂S, Na₂Se, Na₂(S,Se), K₂S, K₂Se, K₂(S,Se), Li₂S, Li₂Se, Li₂(S,Se), Bi₂S₃, Bi₂Se₃, Bi₂(S,Se)₃, SbCl₃, SbBr₃, SbI₃, antimony(III) acetate, antimony(III) tartrate, SbCl₅, SbBr₅, SbF₃, SbF₅, NaCl, NaBr, NaI, NaF, NaOH, sodium acetate, Na₂SO₄, NaNO₂, Na₂S₂O₃, NaNO₃, Na₂SO₃, Na₂SeO₃, KF, KCl, KBr, KI, KOH, potassium acetate, K₂SO₄, K₂S₂O₃ KNO₂, KNO₃, K₂SO₃, K₂S₂O₃, K₂SeO₃, LiF, LiCl, LiBr, LiI, LiOH, lithium acetate, Li₂SO₄, LiNO₃, LiNO₂, Li₂SO₃, Li₂S₂O₃ Li₂SeO₃, BiF₃, BiCl₃, BiBr₃, BiI₃, Bi(NO₃).5H₂O, bismuth(III) acetate, and bismuth(III) citrate.

15. The method of claim 1, wherein the liquid medium comprises a solvent selected from the group consisting of: water, ammonium hydroxide, ammonium hydroxide-water mixtures, ammonium sulfide-ammonium hydroxide-water mixtures, alcohols, ethers, glycols, aldehydes, ketones, alkanes, amines, dimethylsulfoxide (DMSO), cyclic compounds, halogenated organic compounds and combinations comprising at least one of the foregoing solvents.

16. The method of claim 1, wherein the step of contacting the metal chalcogenides in the liquid medium to form the solution or the dispersion is performed before the step of contacting the at least one organic additive with the metal chalcogenides.

17. The method of claim 1, wherein the substrate comprises one or more of a metal foil substrate, aluminum foil coated with a layer of molybdenum, a glass substrate with conductive coating, a ceramic substrate with conductive coating and a polymer substrate with a conductive coating.

18. The method of claim 1, wherein the solution or the dispersion is deposited onto the substrate using spin-coating, dip-coating, doctor blading, curtain coating, slide coating, spraying, slit casting, meniscus coating, screen printing, ink jet printing, pad printing, flexographic printing or gravure printing.

19. The method of claim 1, wherein the layer is annealed at a temperature of from about 300° C. to about 700° C., at a pressure of from about 1 μPa(scal) to about 1×10⁶ Pa(scal) for a duration of from about 10 seconds to about 120 minutes to form the chalcogenide film.

20. The method of claim 1, wherein the annealing step is performed in an atmosphere containing vapors of at least one of S, Se, Sn, SnS, SnSe, SnS₂, SnSe₂.
